(19) United States
(12) Patent Application Publication
(10) Pub. No.: US 2026/0280313 A1
(43) Pub. Date: Sep. 17, 2026

(54) ELECTRONIC COMPONENT INTENDED TO BE EMBEDDED IN A VEHICLE

(71) Applicant: VALEO EAUTOMOTIVE GERMANY GMBH, Erlangen (DE)

(72) Inventors: Jean-Noel FIORINA, Cergy Pontoise (FR); Fred JACQUES, Cergy Pontoise (FR)

(73) Assignee: VALEO EAUTOMOTIVE GERMANY GMBH, Erlangen (DE)

(21) Appl. No.: 19/166,775

(22) PCT Filed: Feb. 22, 2024
(86) PCT No.: PCT/EP2024/054589

§ 371 Date: Sep. 18, 2025

(30) Foreign Application Priority Data
Mar. 24, 2023 (FR) FR2302840

(51) Int. Cl. H02J 7/60; H02J 7/04; H02J 7/70

(52) U.S. Cl. CPC H02J 7/60; H02J 7/04; H02J 7/70

(57) ABSTRACT

An electronic component for charging an electrical energy storage unit, includes a connector able to be connected to an electrical network supplying an AC voltage at a first frequency; and an inverter/rectifier. The component includes a device for detecting an insulation fault between ground and at least one from among the neutral and a phase of the AC voltage. The device includes an input connected to the neutral of the AC voltage, an output connected to ground, a generator for generating an AC voltage at a second frequency lower than the first frequency, and an impedance arranged between the input and the output.

The present invention relates to an electronic component intended to be placed on board a vehicle. Such a component provides, for example, a supply of electric power to a vehicle electrical energy storage unit, and is also called a “charger” for this electrical energy storage unit. The electrical energy storage unit is, for example, a battery, which can have a nominal voltage that is greater than 60 V, for example, greater than or equal to 300 V, 400 V, 800 V, or even 1,000 V. In a known example, this component comprises:
an inverter/rectifier receiving an AC voltage as input and supplying a DC voltage as output; and
a DC/DC converter arranged downstream of the inverter/rectifier and connected to the electrical energy storage unit.

A need exists for further improving such components.

The aim of the invention is to address this need, and it does so, according to one of the aspects thereof, by way of an electronic component for charging an electrical energy storage unit, comprising:
a connector able to be connected to an electrical network supplying an AC voltage at a first frequency;
an inverter/rectifier; and
notably, a DC/DC converter, with the inverter/rectifier being arranged in series between the connector and the DC/DC converter;
the component comprising a device for detecting an insulation fault between ground and at least one from among the neutral and a phase of the AC voltage, with this device comprising:
an input connected to the neutral of the AC voltage;
an output connected to ground;
a generator for generating an AC voltage at a second frequency lower than the first frequency;
an impedance, notably a measuring resistor, arranged between the input and the output, with an insulation fault being detected as a function of the value of an electrical quantity associated with this impedance.

The presence of such a device for detecting an insulation fault allows the electronic component to operate in reverse mode, with a load or the electrical network then being supplied from the electrical energy storage unit. The detection of an insulation fault guarantees the safety of users in contact with the load or the electrical network. The load can be arbitrary, notably incorporating the energy storage unit of another vehicle in a V2V (vehicle-to-vehicle) configuration or any equipment in a dwelling or a premises.

Injecting an AC voltage at the second frequency equally allows an insulation fault to be detected between ground and the neutral and between ground and the phase, using a device for detecting an insulation fault with its input only connected to the neutral of the AC voltage. A connection to the phase of the AC voltage then is not necessary.

Within the component, the neutral and ground are preferably insulated. When the component is on board a vehicle, its chassis is, for example, grounded and the insulation distance and the leakage lines with respect to the chassis then can be compliant with IEC standard 60664-4. Where appropriate, the one or more phases of the AC voltage are also insulated from ground. The insulation distance and the leakage lines of this or these phases with respect to the chassis are compliant, for example, with IEC standard 60664-4.

The device for detecting an insulation fault comprises, for example, a determination system determining the value of the electrical quantity associated with the impedance, for example, the voltage across the terminals of this impedance or the current flowing in this impedance. This determination is undertaken via a measurement, for example.

The device for detecting an insulation fault can comprise a controllable switch, configured to interrupt the flow of current between the input and the impedance. Thus, when it is open this switch prevents any loss of current through the device for detecting an insulation fault.

This controllable switch is an electrotechnical relay, for example. However, the invention is not limited to such an example, with other switches being possible, for example, a static relay based on optical couplers and/or MOSFETs and/or IGBTs.

The electrical quantity associated with the impedance is, for example, the voltage across the terminals of the impedance. As a variant, this electrical quantity is, for example, the current that flows in this impedance.

The impedance is arranged, for example, relative to the input and the output of the device for detecting an insulation fault such that the voltage across the terminals of the impedance is obtained from the voltage between the input and the output of the device for detecting an insulation fault via a voltage divider bridge.

The determination system can comprise:
an amplification stage for amplifying the voltage across the terminals of the impedance; and
a filtering stage for filtering the component that is at the first frequency in this voltage.

Such a determination system allows a signal that is generated based on the voltage at the second frequency to be used to detect an insulation fault. Indeed, when the controllable switch is closed, the flow of a current is permitted through the impedance between the neutral of the AC voltage and ground. In this case, if an insulation fault exists between a phase and ground, a fault resistance then exists between this phase and ground. The phase-neutral voltage for this phase at the first frequency, as well as the voltage generated by the generator of the device for detecting an insulation fault at the second frequency, are then applied to the impedance and to this fault resistance. By applying a voltage divider bridge, it is thus possible to obtain the value of the voltage, both according to its component at the first frequency and according to its component at the second frequency, which is applied across the terminals of the impedance. The filtering stage allows the component to be insulated from this voltage at the second frequency.

If an insulation fault exists between the neutral and ground, a fault resistance then exists between the neutral and ground. The voltage at the second frequency provided by the generator of the device for detecting an insulation fault is then applied to the impedance and to this fault resistance. By applying a voltage divider bridge, it is thus possible to deduce the value of the voltage across the terminals of the impedance. In the absence of an insulation fault between neutral and ground, the voltage across the terminals of the impedance is zero.

The amplification stage of the determination system of the device for detecting an insulation fault can implement differential amplification, and/or the filtering stage can implement a low-pass filter. Differential amplification facilitates the processing of the voltage at the second frequency.

The filtering stage is, for example, a low-pass filter whose cut-off frequency can be 50 Hz. Any other cut-off frequency allowing filtering of the component that is at the first frequency in the voltage across the terminals of the impedance is possible.

The component can comprise a processing unit configured to deduce at least one of the following from the determined voltage value:
an insulation fault between the phase and ground; and
an insulation fault between the neutral and ground.

This processing unit can form part of the device for detecting an insulation fault, for example, the determination system, or can be a processing unit distinct from this device. This processing unit is integrated, for example, into the control module of the inverter/rectifier. In a variant, this one processing unit is integrated, for example, into a transmission control module (TCU), or into a vehicle control module (VCU).

The processing unit is configured, for example, to deduce at least one of the following from the voltage value measured across the terminals of the impedance:
the value of the impedance between the neutral and ground; and
the value of the impedance between the phase and ground.

When the impedance value thus deduced is lower than a threshold value, an insulation fault can be detected and generate alarms. The threshold value is, for example, 500 ′Ω/V, as stipulated by GBT standard 184874-20 XX.

Throughout the above, the ratio between the first frequency and the second frequency can be greater than 5, notably greater than 10. The first frequency is, for example, equal to 50 Hz or to 60 Hz, and the second frequency can range between 1 Hz and 5 Hz, notably being equal to 2 Hz. The voltage supplied by the generator of the device for detecting an insulation fault can have an amplitude of a few V, for example, a voltage ranging between 0 and 5 V. It can be a sinusoidal voltage.

Throughout the above, the component can include an AC current filtering stage, with this filtering stage being arranged in series between the connector and the inverter/rectifier. This filtering stage allows, for example, when the AC voltage is polyphase, filtering of the common-mode current and/or filtering of the differential current.

In this case, the input of the device for detecting an insulation fault can be arranged in series between the filtering stage and the inverter/rectifier. As a variant, the input of the device for detecting an insulation fault can be arranged in series between the filtering stage and the connector.

Throughout the above, the voltage of the network can be polyphase, notably three-phase. This voltage can have a frequency of 50 Hz or 60 Hz and an RMS value of 230 V or 240 V. As a variant, the network voltage can be single-phase.

Throughout the above, the electrical energy storage unit is, for example, a battery, which can have a nominal voltage greater than 60 V, for example, greater than or equal to 300 V, 400 V, 800 V, or even 1,000 V.

Throughout the above, the impedance the determination system is associated with can be a resistor. Other embodiments are possible, such as an inductor or a capacitor.

Throughout the above, the inverter/rectifier and the device for detecting an insulation fault between ground and at least one from among the neutral and a phase of the AC voltage can be contained in the same housing of the component. The inverter/rectifier and the device for detecting an insulation fault are, for example, permanently physically secured together within the component, unlike the case whereby the device for detecting an insulation fault would be housed in an interconnector between the component and the electrical network, with this interconnector then only being electrically connected to the component when the component exchanges electrical energy with the electrical network. The device for detecting an insulation fault is, for example, fully or partly supported by one of the boards of the component, for example, by the power board of the inverter/rectifier of the component and/or by the control board of this inverter/rectifier.

The electronic component can include an inverter/rectifier and a DC/DC converter in the same housing or not in the same housing. The DC/DC converter has, for example, galvanic insulation, notably via a transformer, such as a three-phase transformer. The device for detecting an insulation fault is mounted, for example, on the inverter/rectifier, and it can be received against the internal wall of the housing.

In the event that the housing is common to the inverter/rectifier and to the DC/DC converter, the housing can have two areas with different heights, with one of these areas accommodating the inverter/rectifier and the other one of these areas accommodating the DC/DC converter. The device for detecting an insulation fault then can be received in a protuberance of the highest area.

A further aim of the invention, according to another aspect thereof, is a method for detecting an insulation fault between ground and at least one from among the neutral and a phase of the AC voltage flowing in an electrical circuit comprising:
a connector connected to an electrical network or to a load;
an inverter/rectifier; and
notably, a DC/DC converter, with the inverter/rectifier being arranged in series between the connector and the DC/DC converter;
in which method a device for detecting an insulation fault is used comprising:
an input connected to the neutral of the AC voltage;
an output connected to ground;
a generator for generating an AC voltage at a second frequency lower than the first frequency; an impedance, notably a measuring resistor, arranged between the input and the output, with an insulation fault being detected as a function of the value of an electrical quantity associated with this impedance.

All or some of the aforementioned description with respect to the component also applies to the above method.

The device for detecting an insulation fault can comprise a controllable switch, notably an electrotechnical relay, configured to interrupt the flow of current between the input and the resistor, and this switch can be controlled so as to be closed as long as the current flows from the electrical energy storage unit to the connector.

According to the above method, the inverter/rectifier can be controlled as an inverter, such that the electrical network or the load is supplied with AC voltage from the component.

The invention will be better understood upon reading the following description of non-limiting embodiments thereof:

FIG. 1 shows an electronic component ensuring the supply of electrical power for a vehicle electrical energy storage unit;

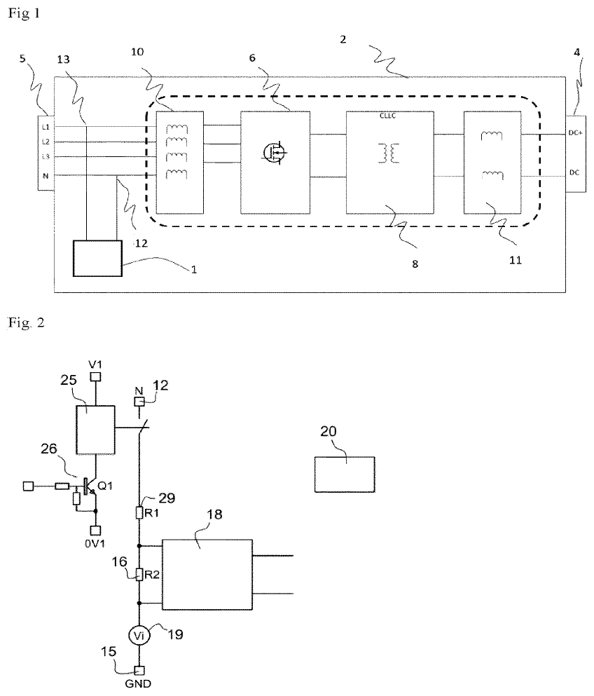

FIG. 2 represents part of the electronic component of FIG. 1, also comprising a device for detecting an insulation fault according to one embodiment of the invention;

FIG. 3 is a model of the component of FIG. 2 in the event of an insulation fault between a phase of the AC voltage and ground;

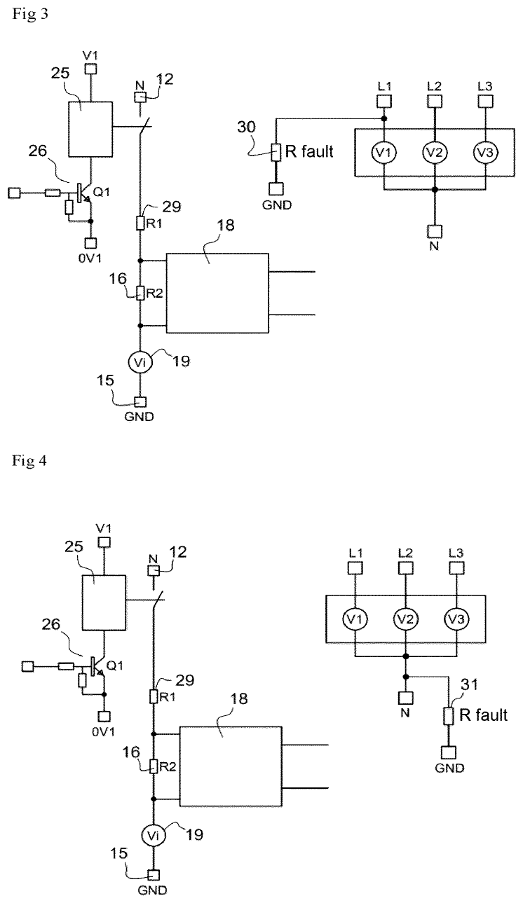

FIG. 4 is a model of the component of FIG. 2 in the event of an insulation fault between the neutral of the AC voltage and ground;

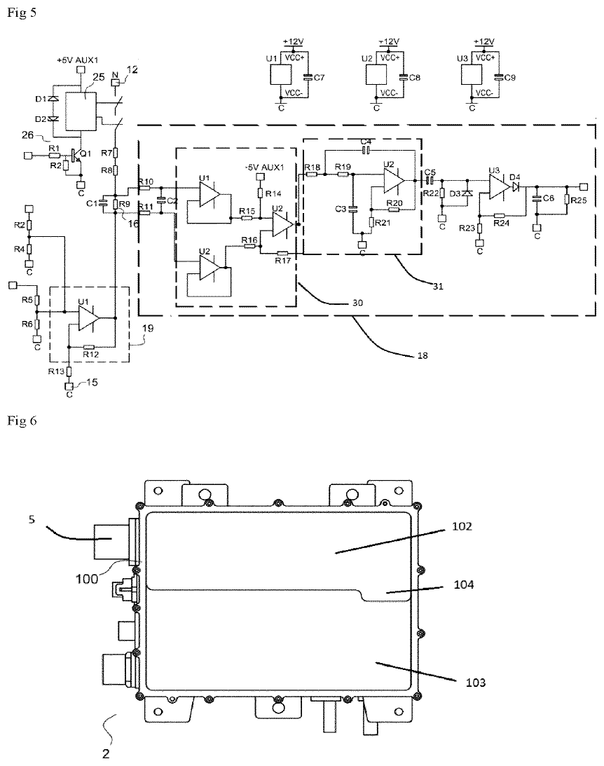

FIG. 5 is a view of FIG. 2 showing an embodiment of the measurement system of the device for detecting an insulation fault; and

FIG. 6 structurally shows an electronic component with its housing.

FIG. 1 shows an electronic component 2 for charging an electrical energy storage unit 4. This electronic component 2 comprises:
a connector 5 able to be connected to an electrical network supplying an AC voltage;
an inverter/rectifier 6; and
a DC/DC converter 8.

As can be seen in FIG. 1, the inverter/rectifier 6 in this case is arranged in series between the connector 5 and the DC/DC converter 8.

The electrical energy storage unit 4 in this case is a battery used for supplying electrical power to an electrical vehicle propulsion machine. This battery has, for example, a nominal voltage greater than 60 V, notably greater than 300 V, notably greater than 400 V, notably greater than 800 V, or even notably 1,000 V.

The electrical network is, for example, a three-phase network conveying a voltage at a first frequency, which is 50 Hz or 60 Hz and whose RMS value is 230 V or 240 V.

As shown in FIG. 1, an AC filtering stage 10 can be provided, with this filtering stage 10 in this case being arranged in series between the connector 5 and the inverter/rectifier 6. This filtering stage 10 allows, for example, when the AC voltage is polyphase, filtering of the common-mode current and/or filtering of the differential current.

Where appropriate, optionally, another DC filtering stage 11 can be present, which is then arranged in series between the DC/DC voltage converter 8 and the electrical energy storage unit 4, as shown in FIG. 1.

The DC/DC voltage converter 8 is, for example, a resonant converter, for example, of the CLLC type.

According to the invention, the component 2 comprises a device for detecting an insulation fault 1 between at least one of the following:
a phase of the AC voltage and ground; and
the neutral of the AC voltage and ground.

According to the example shown in FIG. 2, the device 1 for detecting an insulation fault has an input 12, which can be connected to the AC voltage between the filtering stage 10 and the inverter/rectifier 6 or which can be connected to the AC voltage between the connector 5 and the filtering stage 10. In the example of FIG. 1, the connection of the device for detecting an insulation fault occurs between the connector 5 and the filtering stage 10.

The detection device 1 allows an insulation fault to be detected between ground and the neutral N, or an insulation fault to be detected between a phase L1, L2, L3 of the AC voltage and ground. This detection device 1 also comprises an output 15 connected to ground, an impedance 16, which in this specific example is a measuring resistor, and in this case it comprises a system 18 for determining the voltage across the terminals of this measuring resistor 16. The detection device 1 also comprises a generator 19 supplying an AC voltage at a second frequency, for example, 2 Hz, and whose amplitude can be of the order of a few V, for example, 3V.

The electronic component 2 also comprises a processing unit 20 implementing one or more micro-controllers. This processing unit 20 can be integrated into the detection device 1 and dedicated thereto. Where appropriate, this processing unit is merged with the determination system 18. As a variant, the processing unit 20 forms part of a centralized control module of the vehicle, also called “VCU”, or even of a control module of the inverter/rectifier 6.

FIG. 2 shows that the device 1 comprises, in addition to the aforementioned elements: an electronic switch 25, which in this case is a relay, and its control circuit 26.

It also can be seen that a resistor 29 is mounted in series between the switch 25 and the measuring resistor 16, with this resistor 29 defining a voltage divider bridge type assembly with the measuring resistor 16.

The operation of the device 1 for detecting an insulation fault described with reference to FIG. 2 will now be explained with reference to FIGS. 3 and 4, which respectively model the case of an insulation fault between the phase L1 and ground, and the case of an insulation fault between the neutral N and ground. In this example, current flows from the electrical energy storage unit 4 to the connector 5, and the switch 25 is controlled so as to remain closed.

FIG. 3 corresponds to the case whereby an insulation fault exists between the phase L1 and ground. When the relay 25 is closed, current flows via the input 12 through the resistors 29 and 16, while a fault resistor 30 models the insulation fault between the phase L1 and ground.

By applying the mesh law, it can be seen that the phase-neutral voltage V1 for the phase L1 at the first frequency is then applied to the resistors 16, 29 and 30. It also can be seen that the voltage at the second frequency supplied by the generator 19 is also applied to these resistors 16, 29 and 30. The determination system 18 then receives the voltage applied across the terminals of the measuring resistor 16 as input. This voltage in this case comprises a component at the first frequency and at the second frequency.

The determination system 18 can comprise:
an amplification stage 30 for amplifying the voltage across the terminals of the resistor 16; and
a filtering stage 31 for filtering the component that is at the first frequency in this voltage. This measurement system 18 is shown in further detail in FIG. 5.

In the absence of an insulation fault, the value of the voltage applied to the resistors 29 and 30 is zero.

The value of the voltage determined by the determination system 18 is then used to detect whether or not an insulation fault exists between one of the phases of the network and ground. This detection can be performed by the determination system 18 or by the processing unit 20, and it can involve comparing the value processed by the determination system based on the voltage at the second frequency with a predefined value corresponding to the absence of such an insulation fault.

The detection can involve determining, based on the value processed by the determination system from the voltage at the second frequency, the value of the impedance between the neutral and ground or the value of the impedance between the phase and ground. By comparing this impedance value and a threshold, for example, 500 ′Ω/V, it is possible to determine whether or not an insulation fault exists. Thus, when the impedance value between the neutral and ground or between the phase and ground is less than this threshold, an insulation fault is detected.

FIG. 4 corresponds to the case whereby an insulation fault exists between the neutral N and ground. When the relay 25 is closed, current flows via the input 12 through the resistors 29 and 16, while a fault resistor 31 models the insulation fault between the neutral N and ground.

By applying the mesh law, it can be seen that the voltage at the second frequency supplied by the generator 19 is also applied to the resistors 16, 29 and 31. The measurement system 18 then receives the voltage at the second frequency applied across the terminals of the measuring resistor 16 as input.

As has been described with reference to FIG. 3, the value processed by the determination system 18 from the voltage at the second frequency is then used to detect whether or not an insulation fault exists between one of the phases of the network and ground.

FIG. 5 shows a more specific embodiment of the detection device 1 whose operation has been described above. Notably, it can be seen that the determination system 18 implements several operational amplifiers for carrying out differential amplification as per the amplification stage 30, on the one hand, and low-pass filtering as per the filtering stage 31, on the other hand. The low-pass filter that is used has, for example, a cut-off frequency of 50 Hz.

The measuring resistor 16 has, for example, a value of 5 k′Ω and the other resistors that are used can have any value ranging between 1 k′Ω and 1 M′Ω.

The following resistance values are possible, in a specific example:
R7, R8, R10, R11 R18, R19, R20 have a value of 100 k′Ω;
R1, R2, R13, R14, R15, R16, R17, R23 have a value of 10 k′Ω;
R3 has a value of 75 k′Ω;
R4 has a value of 11.5 k′Ω;
R12 has a value of 50 k′Ω;
R21 has a value of 166 k′Ω;
R22 and R24 have a value of 300 k′Ω; and
R25 has a value of 1 M′Ω.

The component 2 of FIG. 1 is, for example, contained in the same housing 100, as shown in FIG. 6. This housing 100 can have a stepped bottom wall 101, with this bottom wall 101 having two flat portions 102 and 103 parallel to each other and offset from one another. The device 1 described above is received, for example, in a protuberance 104 extending from the highest portion 102, encroaching upon the lowest portion 103.

The filtering stage 10 and the inverter/rectifier 6 of FIG. 1 are arranged, for example, in the part of the housing 100 containing the flat portion 102, while the DC/DC converter 8 is arranged in the part of the housing 100 containing the flat portion 103.

The invention is not limited to the example described above. Embodiments of the impedance 16 other than via a resistor are possible, for example.

In one variant, the AC voltage is single-phase.

1. An electronic component for charging an electrical energy storage unit, comprising:
a connector able to be connected to an electrical network supplying an AC voltage at a first frequency;
an inverter/rectifier; and
notably, a DC/DC converter, with the inverter/rectifier being arranged in series between the connector and the DC/DC converter;
the component comprising a device for detecting an insulation fault between ground and at least one from among the neutral and a phase of the AC voltage, said device comprising:
an input connected to the neutral of the AC voltage;
an output connected to ground;
a generator for generating an AC voltage at a second frequency lower than the first frequency;
an impedance, notably a measuring resistor, arranged between the input and the output, with an insulation fault being detected as a function of the value of an electrical quantity associated with this impedance.

2. The component as claimed in claim 1, the device for detecting an insulation fault comprising a controllable switch, configured to interrupt the flow of current between the input and the impedance.

3. The component as claimed in claim 1, the controllable switch being an electronic relay.

4. The component as claimed in claim 1, the electrical quantity associated with the impedance being the voltage across the terminals of this impedance.

5. The component as claimed in claim 4, the impedance being arranged relative to the input and the output of the device for detecting an insulation fault such that the voltage across the terminals of the impedance is obtained from the voltage between the input and the output of the device for detecting an insulation fault via a voltage divider bridge.

6. The component as claimed in claim 4, the device for detecting an insulation fault comprising:
an amplification stage for amplifying the voltage across the terminals of the impedance and
a filtering stage for filtering the component that is at the first frequency in this voltage across the terminals of the impedance

7. The component as claimed in claim 6, the amplification stage of the device for detecting an insulation fault implementing differential amplification, and/or the filtering stage implementing a low-pass filter.

8. The component as claimed in claim 1, comprising a processing unit configured to deduce at least one of the following from the electrical quantity:
an insulation fault between the phase and ground; and
an insulation fault between the neutral and ground.

9. The component as claimed in claim 1, the ratio between the first frequency and the second frequency being greater than 5, notably greater than 10.

10. The component as claimed in claim 9, the first frequency being equal to 50 Hz or to 60 Hz, and the second frequency ranging between 1 Hz and 5 Hz, notably being equal to 2 Hz.

11. The component as claimed in claim 1, comprising a filtering stage for filtering the AC current at the first frequency, with this filtering stage being arranged in series between the connector and the inverter/rectifier, and the input of the device for detecting an insulation fault being arranged in series between this filtering stage and the inverter/rectifier.

12. The component as claimed in claim 1, comprising a housing, and the inverter/rectifier and the device for detecting an insulation fault between ground and at least one from among the neutral and a phase of the AC voltage being contained in this housing.

13. A method for detecting an insulation fault between ground and at least one from among the neutral and a phase of the AC voltage flowing in an electrical circuit comprising:
a connector connected to an electrical network or to a load;
an inverter/rectifier; and
notably, a DC/DC converter, with the inverter/rectifier being arranged in series between the connector and the DC/DC converter;
in which method a device for detecting an insulation fault is used comprising:
an input connected to the neutral of the AC voltage;
an output connected to ground;
a generator for generating an AC voltage at a second frequency lower than the first frequency;
an impedance, notably a measuring resistor, arranged between the input and the output, with an insulation fault being detected as a function of the value of an electrical quantity associated with this impedance.

14. The method as claimed in claim 13, wherein the device for detecting an insulation fault comprises a controllable switch, notably an electrotechnical relay, configured to interrupt the flow of current between the input and the impedance, and wherein the switch is controlled so as to be closed as long as the current flows from an electrical energy storage unit to the connector.

15. The method as claimed in claim 13, wherein the inverter/rectifier is controlled as an inverter, such that the electrical network or the load is supplied with AC voltage from the component.

16. The component as claimed in claim 2, the controllable switch being an electronic relay.

17. The component as claimed in claim 2, the electrical quantity associated with the impedance being the voltage across the terminals of this impedance.

18. The component as claimed in claim 5, the device for detecting an insulation fault comprising:
an amplification stage for amplifying the voltage across the terminals of the impedance; and
a filtering stage for filtering the component that is at the first frequency in this voltage across the terminals of the impedance.

19. The component as claimed in claim 2, comprising a processing unit configured to deduce at least one of the following from the electrical quantity:
an insulation fault between the phase and ground; and
an insulation fault between the neutral and ground.

20. The component as claimed in claim 2, the ratio between the first frequency and the second frequency being greater than 5, notably greater than 10.
